(19) United States
(12) Patent Application Publication
(10) Pub. No.: US 2018/0135174 A1
(43) Pub. Date: May 17, 2018

(54) COBALT COMPOUNDS, METHOD OF MAKING AND METHOD OF USE THEREOF

(71) Applicant: Versum Materials US, LLC, Tempe, AZ (US)

(72) Inventors: ALAN CHARLES COOPER, MACUNGIE, PA (US); SERGEI VLADIMIROVICH IVANOV, SCHNECKSVILLE, PA (US)

(73) Assignee: Versum Materials US, LLC, Tempe, AZ (US)

(21) Appl. No.: 15/792,092

(22) Filed: Oct. 24, 2017

Related U.S. Application Data
(60) Provisional application No. 62/415,822, filed on Nov. 1, 2016.

(51) Int. Cl. C23C 16/455; C07F 15/06; C23C 16/18; C23C 16/34; C23C 16/42; C23C 16/40; H01L 21/285

(52) U.S. Cl. CPC C23C 16/45553; C07F 15/06; C23C 16/18; H01L 21/28568; C23C 16/42; C23C 16/406; H01L 21/28556; C23C 16/34

(57) ABSTRACT

Described herein are cobalt compounds, processes for making cobalt compounds, and compositions comprising cobalt metal-film precursors used for depositing cobalt-containing films (e.g., cobalt, cobalt oxide, cobalt nitride, etc.). Examples of cobalt precursor compounds are (alkyne) dicobalt hexacarbonyl compounds, cobalt enamine compounds, cobalt monoazadienes, and (functionalized alkyl) cobalt tetracarbonyl. Examples of surfaces for deposition of metal-containing films include, but are not limited to, metals, metal oxides, metal nitrides, and metal silicides. Functionalized ligands with groups such as amino, nitrile, imino, hydroxyl, aldehyde, esters, halogens, and carboxylic acids are used for selective deposition on certain surfaces and/or superior film properties such as uniformity, continuity, and low resistance.

### CROSS-REFERENCE TO RELATED APPLICATIONS

The present patent application claims the benefit of U.S. Provisional Patent Application Ser. No. 62/415,822 filed Nov. 1, 2016. The disclosures of the provisional application is hereby incorporated by reference.

### BACKGROUND OF THE INVENTION

Described herein are cobalt compounds, processes for making cobalt compounds, and compositions comprising cobalt compounds for use in deposition of cobalt-containing films.

Cobalt-containing films are widely used in semiconductor or electronics applications. Chemical Vapor Deposition (CVD) and Atomic Layer Deposition (ALD) have been applied as the main deposition techniques for producing thin films for semiconductor devices. These methods enable the achievement of conformal films (metal, metal oxide, metal nitride, metal silicide, etc.) through chemical reactions of metal-containing compounds (precursors). The chemical reactions occur on surfaces which may include metals, metal oxides, metal nitrides, metal silicides, and other surfaces.

Films of transition metals, particularly manganese, iron, cobalt, and ruthenium, are important for a variety of semiconductor or electronics applications. For example, cobalt thin films are of interest due to their high magnetic permittivity. Cobalt-containing thin films have been used as Cu/low-k barriers, passivation layers, and capping layers for ultra-large scale integrated devices. Cobalt is under consideration for replacement of copper in wiring and interconnects of integrated circuits.

Some Co film deposition precursors have been studied in the art.

US 2016/0115588 A1 discloses cobalt-containing film forming compositions and their use in film deposition.

WO 2015/127092 A1 describes precursors for vapor deposition of cobalt on substrates, such as in ALD and CVD processes for forming interconnects, capping structures, and bulk cobalt conductors, in the manufacture of integrated circuitry and thin film products.

US 2015/0093890 A1 discloses metal precursors and methods comprising decomposing a metal precursor on an integrated circuit device and forming a metal from the metal precursor. The metal precursors are selected from the group consisting of (alkyne) dicobalt hexacarbonyl compounds substituted with straight or branched monovalent hydrocarbon groups having one to six carbon atoms, mononuclear cobalt carbonyl nitrosyls, cobalt carbonyls bonded to one of a boron, indium, germanium and tin moiety, cobalt carbonyls bonded to a mononuclear or binuclear allyl, and cobalt compound comprising nitrogen-based supporting ligands.

WO 2014/118748 A1 describes cobalt compounds, the synthesis of said cobalt compounds, and the use of cobalt compounds in the deposition of cobalt-containing films.

Keunwoo Lee et al. (Japanese Journal of Applied Physics, 2008, Vol. 47, No. 7, pp. 5396-5399) describes deposition of cobalt films by metal organic chemical vapor deposition (MOCVD) using tert-butylacetylene (dicobalt hexacarbonyl) (CCTBA) as cobalt precursor and H₂ reactant gas. The carbon and oxygen impurities in the film decrease with the increase of H₂ partial pressure but lowest amount of amount of carbon in the film was still 2.8 at % at 150° C. Increasing deposition temperature resulted in high impurity contents and a high film resistivity attributed to excessive thermal decompsotion of the CCTBA precursor.

C. Georgi et al. (J. Mater. Chem. C, 2014, 2, 4676-4682) teaches forming Co metal films from (alkyne) dicobalt hexacarbonyl precursors. However, those precursors are undesirable because the films still contain high levels of carbon and/or oxygen resulting in high resistivity. There is also no proof in the literature to support the ability to deposit continuous thin films of Co.

JP2015224227 describes a general synthetic process for producing (alkyne) dicobalt hexacarbonyl compounds. (Tert-butyl methyl acetylene) dicobalt hexacarbonyl (CCTMA) is used to generate cobalt films with low resistivity. However, no improvement in film properties relative to (tert-butylacetylene)dicobalt hexacarbonyl (CCTBA) was demonstrated. Also, (tert-butyl methyl acetylene) dicobalt hexacarbonyl is a high melting (ca. 160° C.) solid. Precursors which are liquid at the precursor delivery temperature, or, more preferably, room temperature, are more desirable.

Generally, limited options exist for ALD and CVD precursors that deliver high purity cobalt films. To enhance film uniformity, film continuity, and electrical properties of the deposited films, the development of novel precursors is necessary and is needed for thin, high-purity cobalt films and bulk cobalt conductors.

### SUMMARY

Described herein are cobalt compounds (or complexes, the terms compounds and complexes are exchangeable), processes for making cobalt compounds, and compositions comprising cobalt metal-film precursors used for depositing cobalt-containing films.

Examples of cobalt precursor compounds described herein, include, but are not limited to, (alkyne) dicobalt hexacarbonyl compounds, cobalt enamine compounds, cobalt monoazadienes, and (functionalized alkyl) cobalt tetracarbonyls. Examples of cobalt-containing films include, but are not limited to cobalt films, cobalt oxide films, and cobalt nitride films. Examples of surfaces for deposition of metal-containing films include, but are not limited to, metals, metal oxides, metal nitrides, and metal silicides.

For certain applications, there is a need for better Co film nucleation and lower film resistivity for thin (1-2 nm) Co films deposited using known Co deposition precursors. As an example, there is a need for better Co film nucleation on TaN and lower film resistivity relative to thin Co films deposited using known Co deposition precursors.

For other applications, there is a need for selective deposition on certain surfaces. For example, selective deposition of cobalt films on copper metal surfaces vs. dielectric surfaces (e.g. SiO₂).

Improved Co film nucleation is achieved by using cobalt compounds with ligands that have a functional group that can interact with the surfaces. Such as, TaN. These functional groups include, but are not limited to, amino, nitrile, imino, hydroxyl, aldehyde, esters and carboxylic acids.

Selective deposition is achieved by using cobalt compounds with ligands that have a functional group that can interact selectively with one surface vs. another surface. Alternatively, selective deposition is achieved by using cobalt compounds that react selectively with one surface vs. another surface.

The interaction of the ligand functional group with the surfaces (such as TaN) can be a combination of Lewis acid/base interactions such as hydrogen bonding. Additionally, the interaction of the ligand functional group with the surface can be a combination of Bronsted acid/base interactions such as deprotonation. Furthermore, interaction of the ligand functional group with the surface can result in breakage of covalent chemical bonds and/or creation of covalent chemical bonds such as Ta—N or Ta—O bonds. Any of these potential interactions or combination of interactions can result in increased affinity of the Co precursor for the TaN surface. Affinity of a cobalt-deposition precursor for one surface vs. an alternate surface allows for selective deposition on a desired surface. In addition, the selective affinity of a cobalt-deposition precursor for one surface can result in improved film uniformity and film continuity for the resulting metal film.

In one embodiment, during the deposition process, cobalt metal is deposited on a metal surface (e.g. copper or cobalt) while no deposition occurs on a dielectric surface (e.g. SiO₂).

In another embodiment, following the deposition process, the cobalt metal film deposited on a metal surface (e.g. copper or cobalt), is preferably >50 times thicker, or, more preferably >200 times thicker, than the cobalt metal film deposited on a dielectric surface (e.g. SiO₂).

In another embodiment, during the deposition process, cobalt metal is deposited on a metal nitride (e.g. tantalum nitride) while no deposition occurs on metal surfaces (e.g. copper or cobalt) or oxide surfaces (e.g. SiO₂).

In another embodiment, following the deposition process, the cobalt metal film deposited on a metal nitride (e.g. tantalum nitride), is preferably >50 times thicker, or, more preferably >200 times thicker, than the cobalt metal film deposited on metal surfaces (e.g. copper or cobalt) or oxide surfaces (e.g. SiO₂).

In another embodiment, influence on metal deposition rate and/or metal film purity can be realized by altering the ligand dissociation energies by modification of the coordinated ligands of the Co film precursor. One method for altering the ligand dissociation energies is the introduction of electron-withdrawing or electron-donating functional groups. In addition, the size of the functional groups on a ligand can alter the ligand dissociation energies. Furthermore, the number of functional groups on a ligand can alter the ligand dissociation energies. An example of influencing ligand dissociation energies is the observed variation of alkyne ligand dissociation energies from mono- and di-substituted (alkyne)dicobalt hexacarbonyl complexes.

In one aspect, the present invention is a cobalt compound selected from the group consisting of:
1) (functionalized alkyne) dicobalt hexacarbonyl compound where dicobalt hexacarbonyl Co₂(CO)₆ is bonded to a structure of:

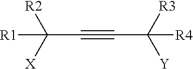

wherein X or Y each individually contains at least one member selected from the group consisting of OR, NR₂, PR₂, and Cl; and R, R₁, R₂, R₃, or R₄ each is individually selected from the group consisting of hydrogen, linear hydrocarbon, branched hydrocarbon, and combinations thereof;
2) (functionalized alkyne) dicobalt hexacarbonyl compound where dicobalt hexacarbonyl Co₂(CO)₆ is bonded to a structure of:

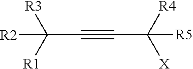

wherein X contains at least one member selected from the group consisting of OR, NR₂, PR₂, and Cl; and R, R₁, R₂, R₃, R₄ or R₅ each is individually selected from the group consisting of hydrogen, linear hydrocarbon, branched hydrocarbon, and combinations thereof;
3) (functionalized alkyne) dicobalt hexacarbonyl compound where dicobalt hexacarbonyl Co₂(CO)₆ is bonded to a structure of:

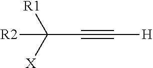

wherein X contains at least one member selected from the group consisting of OR, NR₂, PR₂, and Cl; and R, R₁, or R₂ each is individually selected from the group consisting of hydrogen, linear hydrocarbon, branched hydrocarbon, and combinations thereof;
4) (functionalized allyl) cobalt tricarbonyl compound having a structure of:

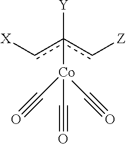

where X, Y, or Z each individually contains at least one member of a group including H, OR, NR₁R₂, PR₁R₂, and Cl; and R, R₁ or R₂ each is individually selected from a group consisting of hydrogen, linear hydrocarbon, branched hydrocarbon, and combinations thereof; and at least one of X, Y and Z is not hydrogen;
5) (enamine)cobalt tricarbonyl compound having a structure of:

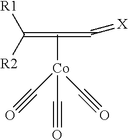

wherein X consists of NR₂, and R, R₁ or R₂ each is individually selected from the group consisting of hydrogen, linear hydrocarbon, branched hydrocarbon, and combinations thereof;
6) (functionalized alkyl) dicobalt tetracarbonyl having a general formula of (XR)Co(CO)₄ wherein X contains at least one member selected from the group consisting of OR, NR₂, PR₂, F and Cl; and R is selected from the group consisting of linear hydrocarbon, branched hydrocarbon, and combinations thereof;
   and
7) (functionalized alkyne) dicobalt hexacarbonyl having mono-substituted alkyne complex containing a primary amine functional group; wherein the mono-substituted alkyne complex and the (functionalized alkyne) dicobalt hexacarbonyl is selected from the group consisting of:
   (a) N,N-Dimethylpropargylamine having a structure of:

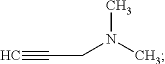

and
the cobalt compound is (N,N-Dimethylpropargylamine) dicobalt hexacarbonyl;
(b) (1,1-Dimethylpropargylamine) having a structure of:

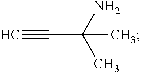

and
the cobalt compound is (1,1-Dimethylpropargylamine) dicobalt hexacarbonyl;
(c) 4-Pentynenitrile having a structure of:

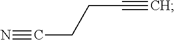

and
the cobalt compound is (4-Pentynenitrile) dicobalt hexacarbonyl;
(d) (1,1-Dimethylpropargylalcohol) having a structure of:

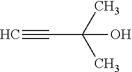

and
the cobalt compound is (1,1-Dimethylpropargylalcohol) dicobalt hexacarbonyl.

In another aspect, the present invention discloses a method of synthesizing the disclosed the cobalt compound.

In yet another aspect, the present invention discloses a method of depositing a Co film on a substrate in a reactor, using the disclosed cobalt compound.

### BRIEF DESCRIPTION OF THE DRAWINGS

The present invention will hereinafter be described in conjunction with the appended figures wherein like numerals denote like elements:

FIG. 1 displays thermogravimetric analysis (TGA) data for (N,N-Dimethylpropargylamine)dicobalt hexacarbonyl measured under flowing nitrogen. The solid line is weight vs. temperature. The dashed line is the first derivative of weight vs. temperature.

FIG. 2 displays thermogravimetric analysis (TGA) data for (1,1-Dimethylpropargylalcohol)dicobalt hexacarbonyl measured under flowing nitrogen. The solid line is weight vs. temperature.

FIG. 3 displays thermogravimetric analysis (TGA) data for Cobalt tricarbonyl [N-methyl-N-[(1,2-q)-2-methyl-1-propenylidene]] measured under flowing nitrogen. The solid line is weight vs. temperature.

FIG. 4 displays thermogravimetric analysis (TGA) data for Cobalt tricarbonyl [N-methyl-N-[(1,2-q)-2-methyl-1-propenylidene]] measured under flowing nitrogen at 60° C. The solid line is weight vs. time.

### DETAILED DESCRIPTION

The ensuing detailed description provides preferred exemplary embodiments only, and is not intended to limit the scope, applicability, or configuration of the invention. Rather, the ensuing detailed description of the preferred exemplary embodiments will provide those skilled in the art with an enabling description for implementing the preferred exemplary embodiments of the invention. Various changes may be made in the function and arrangement of elements without departing from the spirit and scope of the invention, as set forth in the appended claims.

In the claims, letters may be used to identify claimed method steps (e.g. a, b, and c). These letters are used to aid in referring to the method steps and are not intended to indicate the order in which claimed steps are performed, unless and only to the extent that such order is specifically recited in the claims.

Described herein are cobalt compounds, processes for making cobalt compounds, and compositions comprising cobalt metal-film precursors used for depositing cobalt-containing films (e.g., cobalt, cobalt oxide, cobalt silicide cobalt nitride, etc.).

Examples of cobalt precursor compounds include, but are not limited to, (alkyne) dicobalt hexacarbonyl compounds, cobalt enamine compounds, cobalt monoazadienes, and (functionalized alkyl) cobalt tetracarbonyls.

Examples of cobalt-containing films include, but are not limited to cobalt films, cobalt oxide films, cobalt silicide and cobalt nitride films. Examples of surfaces for deposition of metal-containing films include, but are not limited to, metals, metal oxides, metal nitrides, metal silicides, silicon oxide and silicon nitide, and dielectric materials.

One aspect of the current invention is cobalt complexes with ligands that have a functional group that can interact with specific surfaces (e.g. TaN). These functional groups include, but are not limited to, amino, nitrile, imino, hydroxyl, aldehyde, esters and carboxylic acids. Those cobalt compound are used for selective deposition on certain surfaces and/or superior film properties such as uniformity and continuity.

Another embodiment of the cobalt compound is a (functionalized alkyne)dicobalt hexacarbonyl compound where dicobalt hexacarbonyl Co₂(CO)₆ is bonded to a structure shown below:

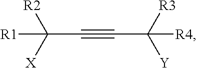

where X or Y each individually contains at least one member selected from a group including OR, NR₂, PR₂, and Cl; and R, R₁, R₂, R₃, or R₄ each is individually selected from a group consisting of hydrogen, linear hydrocarbon, branched hydrocarbon, and combinations thereof.

An example of a disubstituted (difunctionalized alkyne)dicobalt hexacarbonyl compound is (μ-η²,η²-2,5-Dimethyl-3-hexyne-2,5-diol)dicobalt hexacarbonyl:

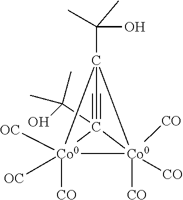

Another embodiment of the cobalt compound is a (functionalized alkyne)dicobalt hexacarbonyl compound where dicobalt hexacarbonyl Co₂(CO)₆ is bonded to a structure shown below:

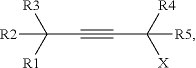

where X contains at least one member selected from a group including OR, NR₂, PR₂, and Cl; and R, R₁, R₂, R₃, R₄ or R₅ each is individually selected from a group consisting of hydrogen, linear hydrocarbon, branched hydrocarbon, and combinations thereof.

An example of a disubstituted (monofunctionalized alkyne)dicobalt hexacarbonyl compound is (μ-[(2,3-η:2,3-η)-2-butyn-1-ol)dicobalt hexacarbonyl:

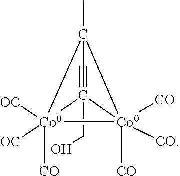

Another embodiment of the cobalt compound is a (functionalized alkyne)dicobalt hexacarbonyl compound where dicobalt hexacarbonyl Co₂(CO)₆ is bonded to a structure shown below:

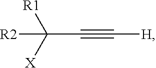

where X contains at least one member selected from the group consisting of OR, NR₂, PR₂, and Cl; and R, R₁, or R₂ each is individually selected from the group consisting of hydrogen, linear hydrocarbon, branched hydrocarbon, and combinations thereof;

An example of a monosubstituted (functionalized alkyne)dicobalt hexacarbonyl compound is (1,1-Dimethylpropargylalcohol)dicobalt hexacarbonyl.

Another embodiment of the cobalt compound is (functionalized allyl)cobalt tricarbonyl compound having the following structure:

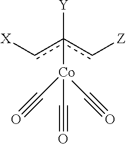

where X, Y, or Z each individually contains at least one member of a group including OR, NR₂, PR₂, and Cl; and R or R₂ each is individually selected from a group consisting of hydrogen, linear hydrocarbon, branched hydrocarbon, and combinations thereof.

where X, Y, or Z each individually contains at least one member of a group including H, OR, NR₁R₂, PR₁R₂, and Cl; and R, R₁ or R₂ each is individually selected from a group consisting of hydrogen, linear hydrocarbon, branched hydrocarbon, and combinations thereof; and at least one of X, Y and Z is not hydrogen.

Yet another embodiment of the cobalt compound is (enamine)cobalt tricarbonyl compound having the following structure:

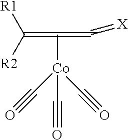

where X consists of NR₂, and R, R₁ or R₂ each is individually selected from a group consisting of hydrogen, linear hydrocarbon, branched hydrocarbon, and combinations thereof. An example of an (enamine)cobalt tricarbonyl compound is Cobalt tricarbonyl [N-methyl-N-[(1,2-η)-2-methyl-1-propenylidene]].

Another embodiment is (functionalized alkyl) cobalt tetracarbonyls, (XR)Co (CO)₄ where X contains at least one member of a group including OR, NR₂, PR₂, F and Cl; and R is selected from a group consisting of linear hydrocarbon, branched hydrocarbon, and combinations thereof. Examples of (functionalized alkyl) cobalt tetracarbonyls are (Methoxymethyl)cobalt tetracarbonyl, (CH₃OCH₂)Co(CO)₄, and (Trifluoromethyl)cobalt tetracarbonyl, (CF₃)Co(CO)₄.

In the series of compounds of the (functionalized alkyne) dicobalt hexacarbonyl family, alkyne ligand functionalizations can generate mono- and di-substituted alkyne compound.

In another embodiment of the current invention, (alkyne) dicobalt carbonyl compounds are synthesized by the reaction of functionalized alkynes with dicobalt octacarbonyl in a suitable solvent (e.g. hexanes, tetrahydrofuran, diethyl ether, and toluene).

For example, the reaction of N,N-Dimethylpropargylamine with dicobalt octacarbonyl results in the displacement of two CO ligands and formation of a dicobalt compound with a bridging N,N-Dimethylpropargylamine ligand. The chemical structure of the bridging N,N-Dimethylpropargylamine ligand shows that the ligand has a tertiary amine group:

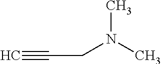

The resulting volatile (N,N-Dimethylpropargylamine) dicobalt hexacarbonyl complex can be distilled under vacuum at 60° C. (20 mTorr) to yield a dark red oil.

Another example of a mono-substituted alkyne complex, containing a primary amine functional group, is realized by a reaction using 1,1-Dimethylpropargylamine having the structure of:

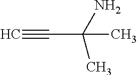

The reaction of 1,1-Dimethylpropargylamine with dicobalt octacarbonyl results in the displacement of two CO ligands and formation of a dicobalt complex with a bridging 1,1-Dimethylpropargylamine ligand. The resulting (1,1-Dimethylpropargylamine) dicobalt hexacarbonyl complex is isolated as a dark red oil which may solidify upon standing at room temperature under inert atmosphere.

An example of a nitrile-functionalized alkyne complex is a cobalt compound that incorporates a 4-Pentynenitrile ligand:

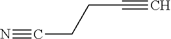

Displacement of two CO ligands can result in the formation of a dicobalt compound with a bridging alkyne ligand. This (4-Pentynenitrile) dicobalt hexacarbonyl complex has a pendant nitrile group which may be coordinated to a cobalt metal center or uncoordinated.

Another example of a functionalized alkyne complex contains a 1,1-dimethylpropargylalcohol ligand:

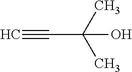

Displacement of two CO ligands can result in the formation of a dicobalt compound with a bridging alkyne ligand as detailed in the reference “Hexacarbonyldicobalt-Alkyne Complexes as Convenient Co₂(CO)₈ Surrogates in the Catalytic Pauson-Khand Reaction”, Belanger, D. et al., Tetrahedron Letters 39 (1998) 7641-7644. This (1,1-Dimethylpropargylalcohol) dicobalt hexacarbonyl complex has a hydroxyl group which may interact with certain surfaces in the cobalt-containing film deposition process.

In another embodiment of the current invention, mononuclear cobalt complexes with functionalized ligands are used as precursors for the deposition of cobalt-containing films.

There are examples of mononuclear cobalt complexes with functionalized ligands in the literature. For example, the reference “Pseudo-Allyl Complexes from Monoazadienes and Co₂(CO)₈ by Activation of Dihydrogen under Mild Conditions”, Beers, O. et al., Organometallics 1992, 11, 3886-3893 describes a synthetic method for preparation of pseudo-allyl complexes with a pendant secondary amino group on the allyl ligand:

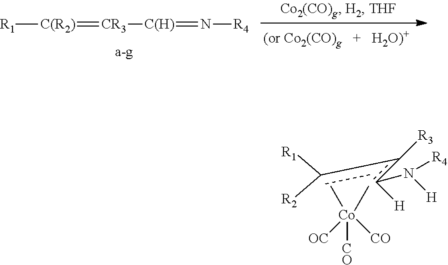

Alkyl groups on the secondary amino group include isopropyl and tert-butyl.

Another example is found in the reference “Organonitrogen Derivatives of Metal Carbonyls. VIII. Reactions of Metal Carbonyl Anions with alpha-Chloroenamines”, King, R. et al., Journal of the American Chemical Society, 1975, 97, 2702-2712. In this reference, treatment of NaCo(CO)₄ with (CH₃)₂C═C(NC₅H₁₀)Cl in tetrahydrofuran solvent yields, after distillation, an air-sensitive oil with the reported structure:

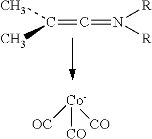

Another example is found in the reference “Alkylcobalt Carbonyls. 9. Alkoxy-, Silyloxy-, and Hydroxy-Substituted Methyl- and Acetylcobalt Carbonyls. Reduction of Formaldehyde to Methanol by Hydridocobalt Tetracarbonyl.”, Sisak, A. et al., Organometallics, 1989, 8, 1096-1100. This reference describes the synthesis of (alkoxymethyl)-, (silyloxymethyl)-, and (hydroxymethyl)cobalt and (alkoxyacetyl)-, (silyloxyacetyl)- and (hydroxyacetyl)cobalt tetracarbonyls such as (methoxymethyl) cobalt tetracarbonyl.

The cobalt complexes or compositions described herein are highly suitable for use as volatile precursors for ALD, CVD, pulsed CVD, plasma enhanced ALD (PEALD) or plasma enhanced CVD (PECVD) for the manufacture of semiconductor type microelectronic devices. Examples of suitable deposition processes for the method disclosed herein include, but are not limited to, cyclic CVD (CCVD), MOCVD (Metal Organic CVD), thermal chemical vapor deposition, plasma enhanced chemical vapor deposition (“PECVD”), high density PECVD, photon assisted CVD, plasma-photon assisted (“PPECVD”), cryogenic chemical vapor deposition, chemical assisted vapor deposition, hot-filament chemical vapor deposition, CVD of a liquid polymer precursor, deposition from supercritical fluids, and low energy CVD (LECVD). In certain embodiments, the cobalt containing films are deposited via atomic layer deposition (ALD), plasma enhanced ALD (PEALD) or plasma enhanced cyclic CVD (PECCVD) process. As used herein, the term “chemical vapor deposition processes” refers to any process wherein a substrate is exposed to one or more volatile precursors, which react and/or decompose on the substrate surface to produce the desired deposition. As used herein, the term “atomic layer deposition process” refers to a self-limiting (e.g., the amount of film material deposited in each reaction cycle is constant), sequential surface chemistry that deposits films of materials onto substrates of varying compositions. Although the precursors, reagents and sources used herein may be sometimes described as “gaseous”, it is understood that the precursors can be either liquid or solid which are transported with or without an inert gas into the reactor via direct vaporization, bubbling or sublimation. In some case, the vaporized precursors can pass through a plasma generator. In one embodiment, the metal-containing film is deposited using an ALD process. In another embodiment, the metal-containing film is deposited using a CCVD process. In a further embodiment, the metal-containing film is deposited using a thermal CVD process. The term “reactor” as used herein, includes without limitation, reaction chamber or deposition chamber.

In certain embodiments, the method disclosed herein avoids pre-reaction of the metal precursors by using ALD or CCVD methods that separate the precursors prior to and/or during the introduction to the reactor.

In certain embodiments, the process employs a reducing agent. The reducing agent is typically introduced in gaseous form. Examples of suitable reducing agents include, but are not limited to, hydrogen gas, hydrogen plasma, remote hydrogen plasma, silanes (i.e., diethylsilane, ethylsilane, dimethylsilane, phenylsilane, silane, disilane, aminosilanes, chlorosilanes), boranes (i.e., borane, diborane), alanes, germanes, hydrazines, ammonia, or mixtures thereof.

The deposition methods disclosed herein may involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, and mixtures thereof. In certain embodiments, a purge gas such as Ar is supplied into the reactor at a flow rate ranging from about 10 to about 2000 sccm for about 0.1 to 10000 seconds, thereby purging the unreacted material and any byproduct that may remain in the reactor.

Energy may be applied to the at least one of the precursor, reducing agent, other precursors or combination thereof to induce reaction and to form the metal-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

The cobalt precursors may be delivered to the reaction chamber such as a CVD or ALD reactor in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, Minn., to enable low volatility materials to be volumetrically delivered, which leads to reproducible transport and deposition without thermal decomposition of the precursor. The precursor compositions described in this application can be effectively used as source reagents in DLI mode to provide a vapor stream of these cobalt precursors into an ALD or CVD reactor.

In certain embodiments, these compositions include those utilizing hydrocarbon solvents which are particularly desirable due to their ability to be dried to sub-ppm levels of water. Exemplary hydrocarbon solvents that can be used in the present invention include, but are not limited to, toluene, mesitylene, cumene (isopropylbenzene), p-cymene (4-isopropyl toluene), 1,3-diisopropylbenzene, octane, dodecane, 1,2,4-trimethylcyclohexane, n-butylcyclohexane, and decahydronaphthalene (decalin). The precursor compositions of this application can also be stored and used in stainless steel containers. In certain embodiments, the hydrocarbon solvent in the composition is a high boiling point solvent or has a boiling point of 100° C. or greater. The cobalt precursor compositions of this application can also be mixed with other suitable metal precursors, and the mixture used to deliver both metals simultaneously for the growth of a binary metal-containing films.

In certain embodiments, the gas lines connecting from the precursor canisters to the reaction chamber are heated to one or more temperatures depending upon the process requirements and the container comprising the composition is kept at one or more temperatures for bubbling. In other embodiments, a composition cobalt precursor is injected into a vaporizer kept at one or more temperatures for direct liquid injection.

A flow of argon and/or other gas may be employed as a carrier gas to help deliver the vapor of the at least one cobalt precursor to the reaction chamber during the precursor pulsing. In certain embodiments, the reaction chamber process pressure is between 1 and 50 torr, preferably between 5 and 20 torr.

Within all of the mononuclear and dinuclear cobalt compounds containing functionalized ligands described herein, the functional groups possess lone pair electrons, acidic or basic protons, unsaturated bonds (e.g. C═O double bond) or other features that promote interactions with specific surfaces. While not being bound by theory, it is believed that the interactions of the ligand functional groups with the TaN surface can be a combination of Lewis acid/base interactions, Bronsted acid/base interactions, and creation of covalent chemical bonds.

Example of a Lewis acid/base interactions are the interaction of lone pair electrons on an amino group or nitrile group (Lewis base) with electron-deficient sites on a TaN surface (Lewis acid). An alternate example of a Lewis acid/base interaction is an interaction of lone pair electrons on TaN surface nitrogen atom (Lewis base) with a hydroxyl proton on a functionalized ligand (Lewis acid) in an interaction analogous to hydrogen bonding.

An example of a Bronsted acid/base interaction is an interaction of an acidic proton on a carboxylic acid-functionalized ligand with a basic site on a TaN surface, resulting in protonation of the surface and formation of a tight ion pair between the protonated site and the anionic metal complex. Alternatively, hydrogen-terminated TaN surfaces could protonate basic sites on a coordinated ligand (e.g. amine-functionalized alkyne ligand).

An alternate example of interactions between a metal complex with a functionalized ligand and a surface is the reaction of a aldehyde-functionalized ligand with a TaN surface, forming new covalent bonds between a tantalum atom on the surface and the oxygen atom of the aldehyde-functionalized ligand.

Any of these potential interactions or combination of interactions can result in increased affinity of the Co precursor for the TaN surface. The increased affinity of a cobalt-deposition precursor for one surface vs. an alternate surface can allow for selective deposition on a desired surface vs. an alternate, accessible surface (e.g. copper). In addition, the selective affinity of a cobalt-deposition precursor for one surface can result in improved film uniformity and film continuity for the resulting metal film through higher precursor coverage on the surface prior to decomposition.

Any of these potential interactions or combination of interactions can also result in increased affinity of the Co precursor for a copper or cobalt metal surface vs. other surfaces (e.g. SiO₂). For example, interaction of lone pair electrons on an amino group or alkoxy group (Lewis base) with electron-deficient metal atoms on the metal surface can result in selectivity for deposition of cobalt on the metal surface.

In another embodiment, influence on metal deposition rate and/or metal film purity can be realized by altering the ligand dissociation energies by modification of the coordinated ligands of the Co film precursor. One method for altering the ligand dissociation energies is the introduction of electron-withdrawing or electron-donating functional groups. Examples of electron withdrawing groups include, but are not limited to, nitrile, ester, carboxylic acid, aldehyde, acid chloride, and trifluoromethyl groups. Examples of electron-donating functional groups include, but are not limited to, tertiary amines, secondary amines, primary amines, hydroxyl, methoxy, alkyl, and trialkylsilyl groups.

In one embodiment, during the deposition process, cobalt metal is deposited on a metal surface (e.g. copper or cobalt) while no deposition occurs on a dielectric surface (e.g. SiO₂).

In another embodiment, following the deposition process, the cobalt metal film deposited on a metal surface (e.g. copper or cobalt), is preferably >50 times thicker, or, more preferably >200 times thicker, than the cobalt metal film deposited on a dielectric surface (e.g. SiO₂).

In another embodiment, during the deposition process, cobalt metal is deposited on a metal nitride (e.g. tantalum nitride) while no deposition occurs on metal surfaces (e.g. copper or cobalt) or oxide surfaces (e.g. SiO₂).

In another embodiment, following the deposition process, the cobalt metal film deposited on a metal nitride (e.g. tantalum nitride), is preferably >50 times thicker, or, more preferably >200 times thicker, than the cobalt metal film deposited on metal surfaces (e.g. copper or cobalt) or oxide surfaces (e.g. SiO₂).

### WORKING EXAMPLES

The following examples have shown the method of making disclosed Co complexes and deposition of Co-containing films using disclosed Co complexes as Co precursors.

In the deposition process, Co precursors are delivered to the reactor chamber by passing 50 sccm argon via stainless steel containers filled with Co precursor. Container temperature is varied from 30° C. to 60° C. to achieve sufficient vapor pressure of the precursor. Wafer temperature is varied between from 125° C. and 200° C. Reactor chamber pressure is varied from 5 to 20 torr. Deposition tests are done in the presence of 500-1000 sccm of hydrogen or argon flow. Deposition time is varied from 20 seconds to 20 minutes for achieving Co films of different thickness.

### Example 1

### Synthesis of (N,N-Dimethylpropargylamine)dicobalt hexacarbonyl

In a ventilated hood, a solution of N,N-Dimethylpropargylamine (5.6 g, 67 mmol) in hexanes (50 mL) was added over 30 minutes to a solution of Co₂(CO)₈ (21.0 g, 61 mmol) in hexanes (150 mL). CO evolution was observed upon addition of each aliquot of N,N-Dimethylpropargylamine solution. The resulting dark red/brown solution was stirred at room temperature for 4 hours. The volatiles were removed under vacuum at room temperature to yield a red brown solid. The solid was redissolved in hexanes (80 mL) and filtered through a pad of Celite 545. The resulting red solution was evaporated to dryness yielding a dark red oil. The (N,N-Dimethylpropargylamine)dicobalt hexacarbonyl complex was distilled under vacuum at 60° C. (20 mTorr) to yield a dark red oil.

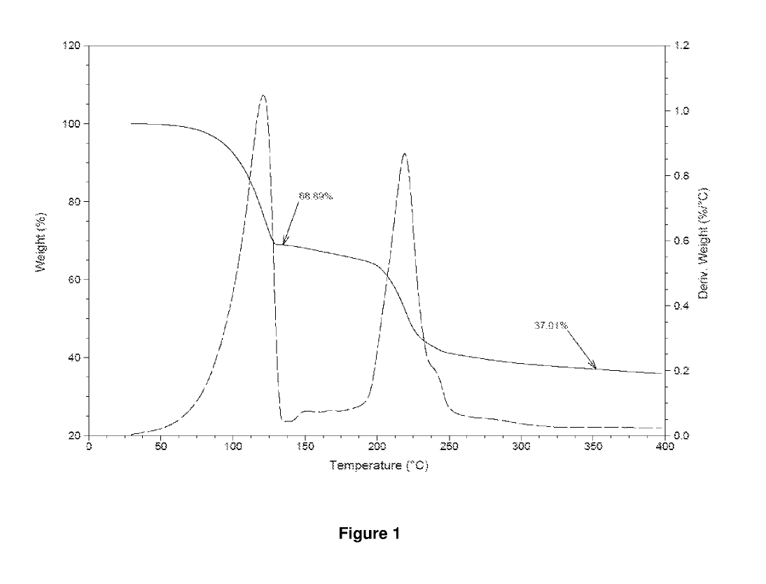

FIG. 1 shows a dynamic TGA analysis of (N,N-Dimethylpropargylamine)dicobalt hexacarbonyl under flowing nitrogen. Upon heating, weight loss is observed in two stages where ˜30% of the weight is lost at temperatures <150° C. and another ˜23% weight is lost up to 350° C. The non-volatile residue at 350° C. is 37%.

### Example 2

### Synthesis of (1,1-Dimethylpropargylalcohol)dicobalt hexacarbonyl

In a ventilated hood, a solution of 1,1-Dimethylpropargylalcohol (5.6 g, 67 mmol) in hexanes (50 mL) was added over 30 minutes to a solution of Co₂(CO)₈ (21.0 g, 61 mmol) in hexanes (150 mL). CO evolution was observed upon addition of each aliquot of 1,1-Dimethylpropargylamine solution. The resulting dark red/brown solution was stirred at room temperature for 4 hours. The volatiles were removed under vacuum at room temperature to yield a red brown solid. The solid was sublimed at 50° C. (100 mTorr) to yield a dark red crystalline product.

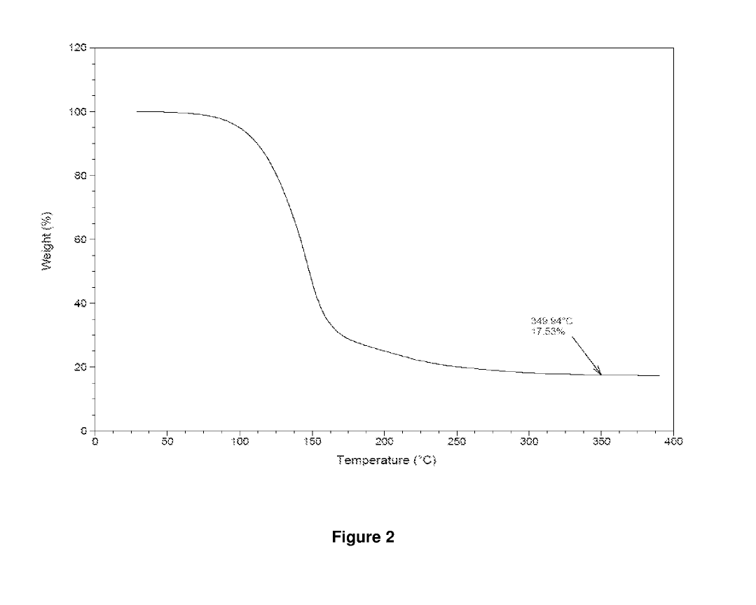

FIG. 2 shows a dynamic TGA analysis of (1,1-Dimethylpropargylalcohol)dicobalt hexacarbonyl under flowing nitrogen. Upon heating, weight loss is observed from 50° C. to 350° C. The non-volatile residue at 350° C. is 17.5%.

### Example 3

### Synthesis of functionalized allyl cobalt tricarbonyl complexes

To a solution of Co₂(CO)₈ (1 mmol) in 20 mL of hydrogen saturated Tetrahydrofuran is added to 3.0 mmol of a monoazadiene compound. After stirring under 1.2 bar H₂ for 24 hours at 20° C., a solution containing the product is obtained. The solution is evaporated to dryness. The product can be purified by column chromatography on silica, using a 20:1 mixture of hexane/dichloromethane as the eluent. The purified product can be isolated by removing the solvents under vacuum.

### Example 4

### Synthesis of Cobalt tricarbonyl [N-methyl-N-[(1,2-η)-2-methyl-1-propenylidene]]

In a nitrogen glovebox, 29.7 g (0.74 mol) of anhydrous sodium hydroxide was ground to a coarse powder using an oven-dried mortar and pestle. Dicobalt octacarbonyl (11.3 g, 33 mmol) was dissolved in 150 mL tetrahydrofuran (THF) with stirring. The sodium hydroxide was added to the THF solution. Within 1 hour of stirring at room temperature, purple precipitate was formed. The solution was filtered in the glovebox using a pad of Celite 545. Using a dropping funnel, (1-Chloro-2-methylprop-1-en-1-yl)dimethylamine (4 g, 30 mmol) was added dropwise as a solution in 60 mL of THF. The solution darkened upon addition and black precipitate formed. The resulting suspension was stirred overnight at room temperature. The suspension was filtered using a pad of Celite 545. The THF was removed under vacuum to yield a small amount of yellow/green oil (˜5 mL) containing black suspended solid. The oil was evaporated at 45° C. under dynamic vacuum (200 mTorr) and transferred to a small flask immersed in a dry ice/acetone bath. After 3 hours, ˜1 mL of yellow oil was transferred.

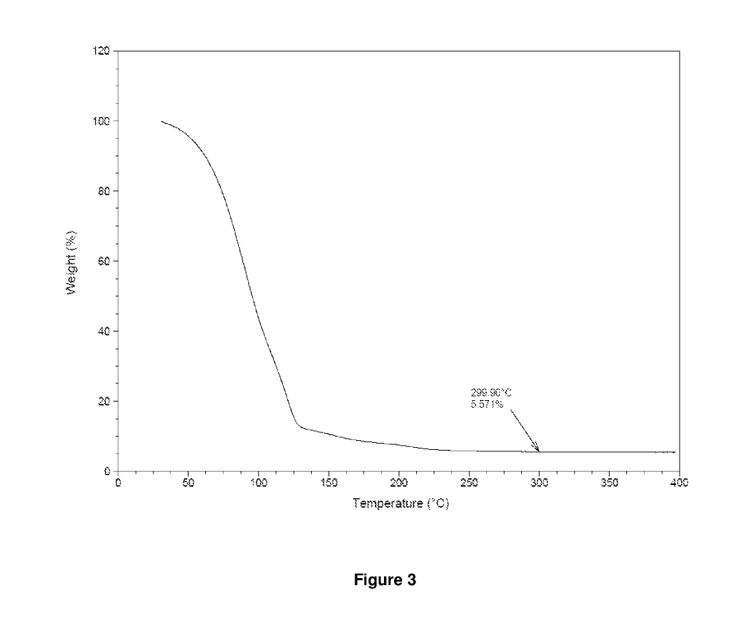

FIG. 3 shows a dynamic TGA analysis of Cobalt tricarbonyl [N-methyl-N-[(1,2-η)-2-methyl-1-propenylidene]] under flowing nitrogen. Upon heating, most of the weight loss is observed from 50° C. to ˜125° C. The non-volatile residue at 300° C. is 5.6%.

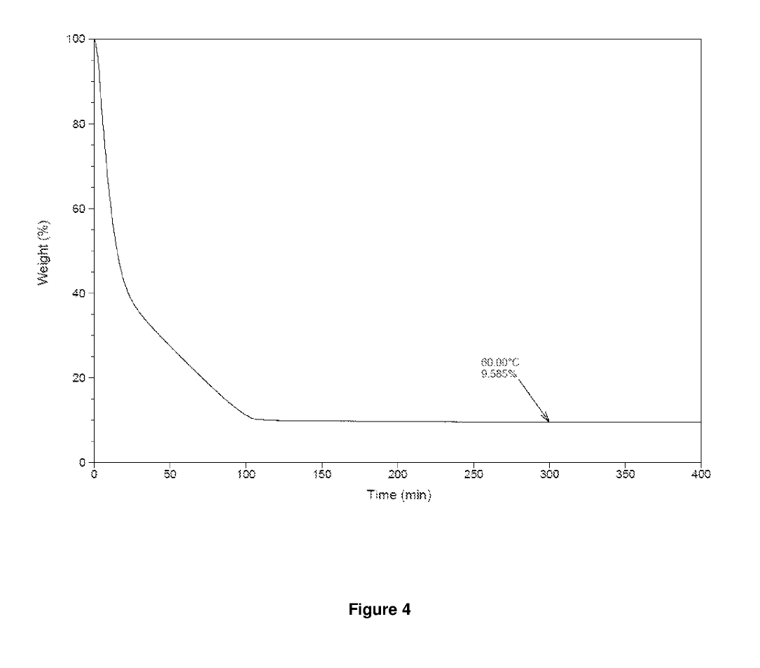

FIG. 4 shows a isothermal TGA analysis of Cobalt tricarbonyl [N-methyl-N-[(1, 2-η)-2-methyl-1-propenylidene]] under flowing nitrogen. Upon heating to 60° C., weight loss is observed over a period of 100 minutes. The non-volatile residue after the weight loss is ˜9.5%.

### Example 5

### Cobalt film formation using Cobalt tricarbonyl [N-methyl-N-[(1,2-η)-2-methyl-1-propenylidene]] as a Co Film Precursor

In a deposition process, Cobalt tricarbonyl [N-methyl-N-[(1,2-η)-2-methyl-1-propenylidene]] is delivered to the reactor chamber by passing 50 sccm argon via stainless steel containers filled with Cobalt tricarbonyl [N-methyl-N-[(1,2-η)-2-methyl-1-propenylidene]]. The container temperature is varied from 30° C. to 60° C. to achieve sufficient vapor pressure of the Cobalt tricarbonyl [N-methyl-N-[(1,2-η)-2-methyl-1-propenylidene]] precursor. The substrate temperature is varied between from 125° C. and 200° C. Reactor chamber pressure is varied from 5 to 20 torr. Deposition tests are done in the presence of 500-1000 sccm of hydrogen or argon flow. Deposition time is varied from 20 seconds to 20 minutes for achieving Co films of different thickness.

The substrates are SiO₂, silicon, tantalum nitride, cobalt, and copper. The deposition process variables are selected to provide conditions for selective deposition of Co-containing films on a desired substrate.

### Example 6

### Preparation of (1,1-Dimethylpropargylalcohol)dicobalt hexacarbonyl solution

Solutions of (1,1-Dimethylpropargylalcohol)dicobalt hexacarbonyl in hexane were prepared by dissolving (1,1-Dimethylpropargylalcohol)dicobalt hexacarbonyl in hexane while stirring using a magnetic stir bar. A solution of ˜50% wt. % (1,1-Dimethylpropargylalcohol)dicobalt hexacarbonyl in hexane was prepared by stirring the solid in hexane at 20° C. for 10 minutes.

While the principles of the invention have been described above in connection with preferred embodiments, it is to be clearly understood that this description is made only by way of example and not as a limitation of the scope of the invention.

1. A method of depositing a Co containing film on a substrate having a first surface in a reactor, comprising:
providing the substrate to the reactor;
providing a Co precursor to the reactor;
contacting the substrate with the Co precursor; and
forming the Co containing film on the substrate;
wherein the Co precursor is selected from the group consisting of:
1) (functionalized alkyne) dicobalt hexacarbonyl compound where dicobalt hexacarbonyl Co₂(CO)₆ is bonded to a structure of: 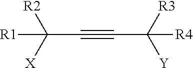
wherein X or Y each individually contains at least one member selected from the group consisting of OR, NR₂, PR₂, and Cl; and R, R₁, R₂, R₃, or R₄ each is individually selected from the group consisting of hydrogen, linear hydrocarbon, branched hydrocarbon, and combinations thereof;
2) (functionalized alkyne) dicobalt hexacarbonyl compound where dicobalt hexacarbonyl Co₂(CO)₆ is bonded to a structure of: 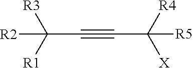
wherein X contains at least one member selected from the group consisting of OR, NR₂, PR₂, and Cl; and R, R₁, R₂, R₃, R₄ or R₅ each is individually selected from the group consisting of hydrogen, linear hydrocarbon, branched hydrocarbon, and combinations thereof;
3) (functionalized alkyne) dicobalt hexacarbonyl compound where dicobalt hexacarbonyl Co₂(CO)₆ is bonded to a structure of: 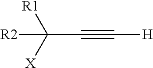
wherein X contains at least one member selected from the group consisting of OR, NR₂, PR₂, and Cl; and R, R₁, or R₂ each is individually selected from the group consisting of hydrogen, linear hydrocarbon, branched hydrocarbon, and combinations thereof;
4) (functionalized allyl) cobalt tricarbonyl compound having a structure of: 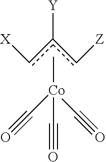
wherein X, Y, or Z each individually contains at least one member selected from the group consisting of OR, NR₂, PR₂, and Cl; and R or R₂ each is individually selected from the group consisting of hydrogen, linear hydrocarbon, branched hydrocarbon, and combinations thereof; wherein X, Y, or Z each individually contains at least one member selected from the group consisting of H, OR, NR₁R₂, PR₁R₂, and Cl; R, R₁ or R₂ each is individually selected from a group consisting of hydrogen, linear hydrocarbon, branched hydrocarbon, and combinations thereof; and at least one of X, Y and Z is not hydrogen;
5) (enamine)cobalt tricarbonyl compound having a structure of: 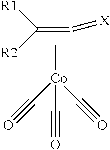
wherein X consists of NR₂, and R, R₁ or R₂ each is individually selected from the group consisting of hydrogen, linear hydrocarbon, branched hydrocarbon, and combinations thereof;
6) (functionalized alkyl) dicobalt tetracarbonyl having a general formula of (XR)Co(CO)₄ wherein X contains at least one member selected from the group consisting of OR, NR₂, PR₂, F and Cl; and R is selected from the group consisting of linear hydrocarbon, branched hydrocarbon, and combinations thereof; and
7) (functionalized alkyne) dicobalt hexacarbonyl having mono-substituted alkyne complex containing a primary amine functional group; wherein the mono-substituted alkyne complex and the (functionalized alkyne) dicobalt hexacarbonyl is selected from the group consisting of:
(a) N,N-Dimethylpropargylamine having a structure of: 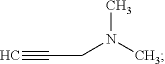
and
the cobalt compound is (N,N-Dimethylpropargylamine) dicobalt hexacarbonyl;
(b) (1,1-Dimethylpropargylamine) having a structure of: 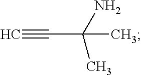
and
the cobalt compound is (1,1-Dimethylpropargylamine) dicobalt hexacarbonyl;
(c) 4-Pentynenitrile having a structure of: 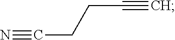
and
the cobalt compound is (4-Pentynenitrile) dicobalt hexacarbonyl;
(d) (1,1-Dimethylpropargylalcohol) having a structure of: 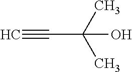
and
the cobalt compound is (1,1-Dimethylpropargylalcohol) dicobalt hexacarbonyl.

2. The method of claim 1, wherein the Co precursor of 1) is (μ-η²,η²-2,5-Dimethyl-3-hexyne-2,5-diol)dicobalt hexacarbonyl:

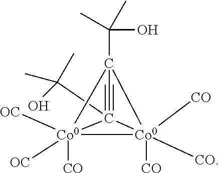

3. The method of claim 1, wherein the Co precursor of 2) is (μ-[(2,3-η:2,3-η)-2-butyn-1-ol)dicobalt hexacarbonyl:

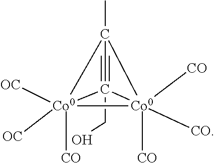

4. The method of claim 1, wherein the Co precursor of 3) is (1,1-Dimethylpropargylalcohol)dicobalt hexacarbonyl.

5. The method of claim 1, wherein the Co precursor of 5) is cobalt tricarbonyl [N-methyl-N-[(1,2-η)-2-methyl-1-propenylidene]].

6. The method of claim 1, wherein the Co precursor of 6) is selected from the group consisting of (Methoxymethyl)cobalt tetracarbonyl, (CH₃OCH₂)Co(CO)₄, and (Trifluoromethyl)cobalt tetracarbonyl, (CF₃)Co(CO)₄.

7. The method of claim 1, wherein the Co precursor is (1,1-Dimethylpropargylalcohol) dicobalt hexacarbonyl.

8. The method of claim 1, wherein the substrate is selected from a group consisting of silicon, silicon oxide, PVD TaN, copper, cobalt, metal nitride and combinations thereof.

9. The method of claim 1, wherein the Co containing film is selected from a group consisting of cobalt film, cobalt oxide film, cobalt silicide film, cobalt nitride film, and combinations thereof.

10. The method of claim 1, wherein the Co film is deposited by a method selected from a group consisting of thermal CVD, thermal ALD, plasma-enhanced ALD (PEALD), plasma enhanced chemical vapor deposition (PECVD), and plasma enhanced cyclic chemical vapor deposition (PECCVD).

11. The method of claim 1, wherein the substrate has a first surface and a second surface; and
(1) the Co film is deposited on the first surface while no deposition occurs on the second surface; or
(2) thickness of the Co containing film deposited on the first surface is more than 50 times of thickness of the Co containing film deposited on the second surface.

12. The method of claim 12, wherein the first surface is a metal surface; and the second surface is a dielectric surface.

13. The method of claim 13, wherein the metal is copper or cobalt; and the second surface is SiO₂.

14. The method of claim 12, wherein the first surface is metal nitride and the second surface is a metal surface or a dielectric surface.

15. The method of claim 15, wherein the first surface is tantalum nitride; and the second surface is a surface selected from the group consisting of copper, cobalt, SiO₂ and combinations thereof.
